(19) United States
(12) Patent Application Publication
(10) Pub. No.: US 2025/0380350 A1
(43) Pub. Date: Dec. 11, 2025

(54) MULTILAYER SUBSTRATE AND ELECTRONIC DEVICE

(71) Applicant: Murata Manufacturing Co., Ltd., Nagaokakyo-shi (JP)

(72) Inventors: Nobuo IKEMOTO, Nagaokakyo-shi (JP); Masanori OKAMOTO, Nagaokakyo-shi (JP)

(21) Appl. No.: 19/308,494

(22) Filed: Aug. 25, 2025

Related U.S. Application Data
(63) Continuation of application No. PCT/JP2024/005307, filed on Feb. 15, 2024.

(30) Foreign Application Priority Data
Mar. 17, 2023 (JP) 2023-043160

(51) Int. Cl. H05K 1/02

(52) U.S. Cl. CPC H05K 1/0201; H05K 1/0242; H05K 2201/0141; H05K 2201/064

(57) ABSTRACT

A multilayer substrate includes a stacked body and a first conductor layer. The stacked body includes insulator layers stacked in a stacking direction. The first conductor layer is provided in the stacked body. In the stacked body, interior spaces that are not connected to a space outside the stacked body are provided. The first conductor layer includes a first principal surface and a second principal surface including an exposed portion exposed to the interior spaces. A surface roughness of the exposed portion is greater than a surface roughness of the first principal surface.

### CROSS REFERENCE TO RELATED APPLICATIONS

This application claims the benefit of priority to Japanese Patent Application No. 2023-043160 filed on Mar. 17, 2023 and is a Continuation Application of PCT Application No. PCT/JP2024/005307 filed on Feb. 15, 2024. The entire contents of each application are hereby incorporated herein by reference.

### BACKGROUND OF THE INVENTION

### 1. Field of the Invention

The present invention relates to multilayer substrates in each of which a plurality of insulator layers are stacked on each other.

### 2. Description of the Related Art

As an invention related to the conventional multilayer substrate, for example, a transmission line disclosed in Japanese Unexamined Patent Application Publication No. 2022-136284 is known. This transmission line has a structure in which a signal line conductor is provided in an insulating base material.

Incidentally, in the field of the transmission line disclosed in Japanese Unexamined Patent Application Publication No. 2022-136284, an improvement in heat dissipation of the transmission line and an improvement in electrical characteristics of the transmission line have been demanded.

### SUMMARY OF THE INVENTION

Example embodiments of the present invention provide multilayer substrates that each achieve improvement in heat dissipation and improvement in electrical characteristics of a multilayer substrate path.

A multilayer substrate according to an example embodiment of the present invention includes a stacked body and a first conductor layer, the stacked body includes a plurality of insulator layers stacked in a stacking direction, the first conductor layer is provided in the stacked body, an interior space is provided in the stacked body, the first conductor layer includes a first principal surface and a second principal surface, the second principal surface includes an exposed portion exposed to the interior space, and a surface roughness of the exposed portion is greater than a surface roughness of the first principal surface.

With multilayer substrates and electronic devices according to example embodiments of the present invention, improvement in heat dissipation of a transmission line and improvement in electrical characteristics of a transmission line are achieved.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is an exploded perspective view of a multilayer substrate 10 according to an example embodiment of the present invention.

FIG. 2 is a cross-sectional view of a multilayer substrate 10 according to an example embodiment of the present invention.

FIG. 3 is a cross-sectional view of a multilayer substrate 10a according to an example embodiment of the present invention.

FIG. 4 is a cross-sectional view of a multilayer substrate 10b according to an example embodiment of the present invention.

FIG. 5 is a cross-sectional view of a multilayer substrate 10c according to an example embodiment of the present invention.

FIG. 6 is a cross-sectional view of a multilayer substrate 10d according to an example embodiment of the present invention.

FIG. 7 is a cross-sectional view of a multilayer substrate 10e according to an example embodiment of the present invention.

FIG. 8 is a cross-sectional view of an electronic device 1 including a multilayer substrate 10 according to an example embodiment of the present invention.

FIG. 9 shows an example of a cross-sectional photograph capturing an upper principal surface and a lower principal surface of a signal conductor layer 20.

### DETAILED DESCRIPTION OF THE EXAMPLE EMBODIMENTS

Example embodiments of the present invention will be described in detail below with reference to the drawings.

### EXAMPLE EMBODIMENTS

### Structure of Multilayer Substrate

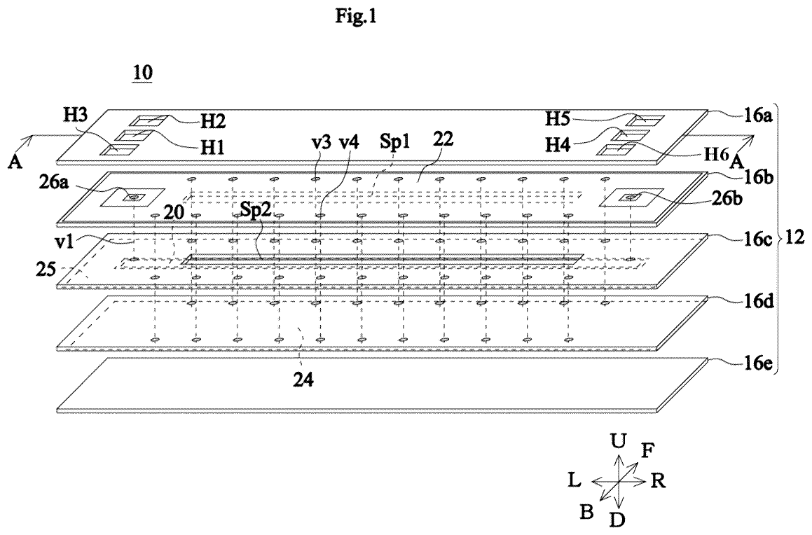

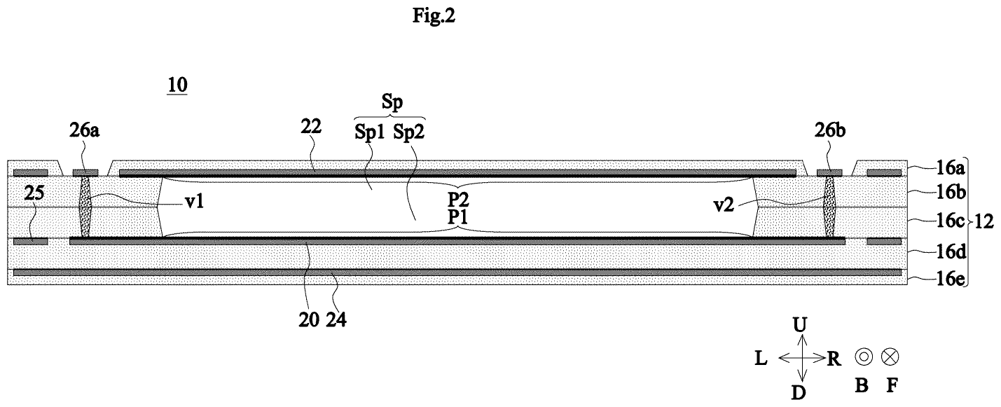

Hereinafter, a structure of a multilayer substrate 10 according to an example embodiment of the present invention will be described with reference to drawings. FIG. 1 is an exploded perspective view of the multilayer substrate 10. FIG. 2 is a cross-sectional view of the multilayer substrate 10. FIG. 2 shows a section taken along a line A-A in FIG. 1. It is to be noted that, in FIG. 1, reference signs are assigned only to the representative interlayer connection conductors v3 and v4 of a plurality of interlayer connection conductors v3 and v4.

In the present specification, directions are defined as follows. A stacking direction of a stacked body 12 of the multilayer substrate 10 is parallel or substantially parallel to an up-down axis. In addition, a direction in which a signal conductor layer 20 of the multilayer substrate 10 extends is parallel or substantially parallel to a left-right axis. In addition, when viewed in the downward direction, a line width direction of the signal conductor layer 20 is parallel or substantially parallel to a front-back axis. The up-down axis, the front-back axis, and the left-right axis are orthogonal or substantially orthogonal to each other. Each of the up-down axis, the left-right axis, and the front-back axis may not coincide with the up-down axis, the left-right axis, and the front-back axis at the time of use of the multilayer substrate 10.

Hereinafter, X is a component or member of the multilayer substrate 10. In the present specification, each portion of X is defined as follows unless otherwise specified. The front portion of X means the front half of X. The rear portion of X means the rear half of X. The left portion of X means the left half of X. The right portion of X means the right half of X. The upper portion of X means the upper half of X. The lower portion of X means the lower half of X. The front end of X means an end of X in the front direction. The rear end of X means an end of X in the rear direction. The left end of X means an end of X in the left direction. The right end of X means an end of X in the right direction. The upper end of X means an end of X in the up direction. The lower end of X means an end of X in the down direction. The front end portion of X means the front end of X and the vicinity. The rear end portion of X means the rear end of X and the vicinity. The left end portion of X means the left end of X and the vicinity. The right end portion of X means the right end of X and the vicinity. The upper end portion of X means the upper end of X and the vicinity. The lower end portion of X means the lower end of X and the vicinity.

First, the structure of the multilayer substrate 10 will be described with reference to FIG. 1 and FIG. 2. The multilayer substrate 10 transmits a high-frequency signal. The multilayer substrate 10, in an electronic device such as a smartphone, for example, is used in order to electrically connect two circuits. The multilayer substrate 10, as shown in FIG. 1, includes a stacked body 12, a signal conductor layer 20 (a first conductor layer), a ground conductor layer 22 (a second conductor layer), a ground conductor layer 24, a ground conductor layer 25, mounting electrodes 26a and 26b, interlayer connection conductors v1 and v2, a plurality of interlayer connection conductors v3, and a plurality of interlayer connection conductors v4.

The stacked body 12 has a plate shape. Accordingly, the stacked body 12 includes an upper principal surface and a lower principal surface located below the upper principal surface. The upper principal surface and lower principal surface of the stacked body 12 have a rectangular or substantially rectangular shape including long sides extending along the left-right axis. Accordingly, a length of the stacked body 12 in the left-right axis is longer than a length of the stacked body 12 in the front-back axis. The stacked body 12 has flexibility.

The stacked body 12, as shown in FIG. 1, has a structure in which a plurality of insulator layers 16a-16e are stacked in the stacking direction. Each of the insulator layers 16a-16e includes an upper principal surface and a lower principal surface. The insulator layers 16a-16e are arranged in this order from the top to the bottom. A material of the insulator layers 16a-16e is, for example, a resin having a water absorption rate of about 0.1% or less. The material of the insulator layers 16a-16e is, for example, a thermoplastic resin. The thermoplastic resin is, for example, a liquid crystal polymer. In this manner, the material of the insulator layers 16a-16e is a flexible resin. Then, the insulator layers 16a-16e are fused between adjacent ones in the stacking direction.

The high-frequency signal is transmitted to the signal conductor layer 20. The signal conductor layer 20 (the first conductor layer), as shown in FIG. 1, is provided in the stacked body 12. The signal conductor layer 20 (the first conductor layer) includes an upper principal surface (a second principal surface) and a lower principal surface (a first principal surface). The signal conductor layer 20, as shown in FIG. 1, adheres to the lower principal surface of the insulator layer 16c. Therefore, a surface roughness of the upper principal surface (the second principal surface) of the signal conductor layer 20 is greater than a surface roughness of the lower principal surface (the first principal surface) of the signal conductor layer 20. The signal conductor layer 20 has a linear shape extending along the left-right axis.

The ground conductor layer 22 (the second conductor layer), as shown in FIG. 1, is provided in the stacked body 12. The ground conductor layer 22 includes an upper principal surface and a lower principal surface. The ground conductor layer 22 is located above the signal conductor layer 20 and, when viewed in the down direction, overlaps with the signal conductor layer 20. In the present example embodiment, the ground conductor layer 22 adheres to the upper principal surface of the insulator layer 16b. Therefore, the surface roughness of the lower principal surface of the ground conductor layer 22 is greater than the surface roughness of the upper principal surface of the ground conductor layer 22. The ground conductor layer 22 covers the entire or substantially the entire surface of the upper principal surface of the insulator layer 16b. A ground potential is connected to the ground conductor layer 22.

The ground conductor layer 24, as shown in FIG. 1, is provided in the stacked body 12. The ground conductor layer 24 includes an upper principal surface and a lower principal surface. The ground conductor layer 24 is located below the signal conductor layer 20 and, when viewed in the down direction, overlaps with the signal conductor layer 20. In the present example embodiment, the ground conductor layer 24 adheres to the lower principal surface of the insulator layer 16d. Therefore, the surface roughness of the upper principal surface of the ground conductor layer 24 is greater than the surface roughness of the lower principal surface of the ground conductor layer 24. In addition, the ground conductor layer 24 covers the entire or substantially the entire surface of the lower principal surface of the insulator layer 16d. A ground potential is connected to the ground conductor layer 24. The signal conductor layers 20, the ground conductor layer 22, and the ground conductor layer 24 that are described above have a stripline structure.

The ground conductor layer 25, as shown in FIG. 1, is provided in the stacked body 12. The ground conductor layer 25 includes an upper principal surface and a lower principal surface. The ground conductor layer 25 is located below the ground conductor layer 22 and is located above the ground conductor layer 24. In the present example embodiment, the ground conductor layer 25 adheres to the lower principal surface of the insulator layer 16c. Therefore, the surface roughness of the upper principal surface of the ground conductor layer 25 is greater than the surface roughness of the lower principal surface of the ground conductor layer 25. In addition, the ground conductor layer 25 covers the entire or substantially the entire surface of the lower principal surface of the insulator layer 16c. However, the ground conductor layer 25 is not in contact with the signal conductor layer 20. Therefore, the ground conductor layer 25 includes an opening. Then, the signal conductor layer 20 is located in the opening. A ground potential is connected to the ground conductor layer 25.

The mounting electrode 26a, as shown in FIG. 1, is provided in the stacked body 12. The mounting electrode 26a is located in the left end portion of the upper principal surface of the insulator layer 16b. The mounting electrode 26a, when viewed in the down direction, overlaps with the left end portion of the signal conductor layer 20. The mounting electrode 26a, when viewed in the down direction, has a rectangular or substantially rectangular shape. The mounting electrode 26a is an external terminal that inputs and outputs the high-frequency signal. The mounting electrode 26a is not in contact with the ground conductor layer 22. Since the structure of the mounting electrode 26b is bilaterally symmetrical to the structure of the mounting electrode 26a, the description is omitted.

The interlayer connection conductor v1, as shown in FIG. 1, is provided in the stacked body 12. The interlayer connection conductor v1, as shown in FIG. 1 and FIG. 2, electrically connects the mounting electrode 26a and the left end portion of the signal conductor layer 20. The interlayer connection conductor v1 passes through the insulator layers 16b and 16c along the up-down axis. The upper end portion of the interlayer connection conductor v1 is in contact with the mounting electrode 26a. The lower end portion of the interlayer connection conductor v1 is in contact with the left end portion of the signal conductor layer 20. Since the structure of the interlayer connection conductor v2 is bilaterally symmetrical to the structure of the interlayer connection conductor v1, the description is omitted.

The plurality of interlayer connection conductors v3, as shown in FIG. 1, are provided in the stacked body 12. The plurality of interlayer connection conductors v3 are located in front of the signal conductor layer 20. The plurality of interlayer connection conductors v3 are arranged in a line along the signal conductor layer 20. The plurality of interlayer connection conductors v3, as shown in FIG. 1, electrically connect the ground conductor layer 22, the ground conductor layer 24, and the ground conductor layer 25. The plurality of interlayer connection conductors v3 pass through the insulator layers 16b-16d along the up-down axis. The upper end portion of the plurality of interlayer connection conductors v3 is in contact with the ground conductor layer 22. The lower end portion of the plurality of interlayer connection conductors v3 is in contact with the ground conductor layer 24. An intermediate portion of the plurality of interlayer connection conductors v3 is in contact with the ground conductor layer 25.

The plurality of interlayer connection conductors v4, as shown in FIG. 1, are provided in the stacked body 12. The plurality of interlayer connection conductors 4 are located in the rear of the signal conductor layer 20. The plurality of interlayer connection conductors v4 are arranged in a line along the signal conductor layer 20. The plurality of interlayer connection conductors v4, as shown in FIG. 1, electrically connect the ground conductor layer 22, the ground conductor layer 24, and the ground conductor layer 25. The plurality of interlayer connection conductors v4 pass through the insulator layers 16b-16d along the up-down axis. The upper end portion of the plurality of interlayer connection conductors v4 is in contact with the ground conductor layer 22. The lower end portion of the plurality of interlayer connection conductors v4 is in contact with the ground conductor layer 24. An intermediate portion of the plurality of interlayer connection conductors v4 is in contact with the ground conductor layer 25.

Rectangular or substantially rectangular shaped openings H1-H6 are provided in the insulator layer 16a. The opening H1, when viewed in the down direction, overlaps with the mounting electrode 26a. According to this, the mounting electrode 26a is exposed to the outside from the multilayer substrate 10. The opening H2 is located in front of the opening H1. A portion of the ground conductor layer 22 is exposed to the outside from the multilayer substrate 10 through the opening H2. The opening H3 is located in the rear of the opening H1. A portion of the ground conductor layer 22 is exposed to the outside from the multilayer substrate 10 through the opening H3. According to this, a portion of the ground conductor layer 22 defines and functions as a ground terminal. Since the structure of the openings H4-H6 is bilaterally symmetrical to the structure of the openings H1-H3, the description is omitted.

The signal conductor layers 20, the ground conductor layer 22, the ground conductor layer 24, the ground conductor layer 25, and the mounting electrodes 26a and 26b that are described above are, for example, formed by performing etching of a metal foil provided on the upper principal surface or the lower principal surface of the insulator layers 16b-16d. The metal foil is, for example, a copper foil.

In addition, the interlayer connection conductors v1-v4 are, for example, via-hole conductors. The interlayer connection conductors v1-v4 are formed by, for example, filling conductive paste in the through hole provided in the insulator layers 16b-16d and by solidifying the conductive paste by heating. A material of the conductive paste is, for example, a mixture of a resin and a metal.

As shown in FIG. 2, an interior space Sp is provided in the stacked body 12. The interior space Sp is an enclosed space that is not connected to a space outside the stacked body 12. The interior space Sp is located in the stacking direction between the signal conductor layer 20 (the first conductor layer) and the ground conductor layer 22 (the second conductor layer). More specifically, the insulator layer 16b includes a through hole Sp1 that passes through the insulator layer 16b along the up-down axis. The through hole Sp1, when viewed in the down direction, has a rectangular or substantially rectangular shape. The through hole Sp1 extends along the signal conductor layer 20. In the present example embodiment, the through hole Sp1, when viewed in the down direction, overlaps with the signal conductor layer 20 and the ground conductor layers 22 and 24.

The insulator layer 16c includes a through hole Sp2 that passes through the insulator layer 16c along the up-down axis. The through hole Sp2, when viewed in the down direction, has a rectangular or substantially rectangular shape. The through hole Sp2 extends along the signal conductor layer 20. In the present example embodiment, the through hole Sp2, when viewed in the down direction, overlaps with the signal conductor layer 20 and the ground conductor layers 22 and 24.

The through hole Sp1 and the through hole Sp2 connected to each other define the interior space Sp. Then, at least a portion of the signal conductor layer 20, when viewed in the stacking direction, overlaps with the interior space Sp. Further, the upper principal surface (the second principal surface) of the signal conductor layer 20 includes an exposed portion P1 exposed to the interior space Sp. Then, the surface roughness of the exposed portion P1 is greater than the surface roughness of the lower principal surface (the first principal surface) of the signal conductor layer 20. Similarly, the lower principal surface of the ground conductor layer 22 includes an exposed portion P2 exposed to the interior space Sp. Then, the surface roughness of the exposed portion P2 is greater than the surface roughness of the upper principal surface of the ground conductor layer 22.

### Advantageous Effects

The high-frequency signal is transmitted to the signal conductor layer 20. In order to reduce a transmission loss of the high-frequency signal, the insulator layer between the signal conductor layer 20 and the ground conductor layer 22 is made air with a low dielectric loss tangent, which makes it possible to reduce a dielectric loss due to the insulator layer. In addition, since the air has a low dielectric constant and capacitance between the signal conductor layer 20 and the ground conductor layer 22 is reduced, even when a line width of the signal conductor layer 20 is increased in comparison to a case in which there is no air, a desired characteristic impedance is able to be obtained. As a result, the conductor loss of the signal conductor layer 20 is reduced and a loss is reduced.

However, when the insulator layer is made air, thermal conductivity is reduced and a heat dissipation amount of heat generated in the signal conductor layer 20 is reduced. Then, the surface roughness of the signal conductor layer 20 and the ground conductor layer 22 on a side of an air layer is increased and a surface area is increased, so that the heat dissipation amount of the signal conductor layer 20 is increased and a heat absorption amount of the ground conductor layer 22 is increased, which makes it possible to efficiently convey the heat generated in the signal conductor layer 20 to a product periphery.

### First Modification

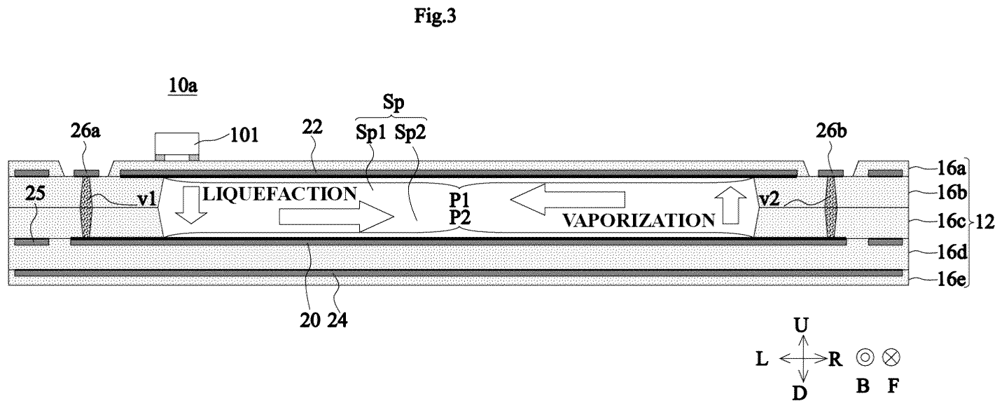

Hereinafter, a multilayer substrate 10a according to a first modification of an example embodiment of the present invention will be described with reference to drawings. FIG. 3 is a cross-sectional view of the multilayer substrate 10a.

The multilayer substrate 10a is different from the multilayer substrate 10 in that an electronic component 101 is further provided. Furthermore, in the interior space Sp, a fluid that vaporizes at, for example, about 25 degrees or more to about 200 degrees or less is present. The fluid is, for example, water. In addition, in the present modification, the ground conductor layer 22 is the first conductor layer. The electronic component 101 is mounted on the upper principal surface of the stacked body 12. The electronic component 101, when viewed in the down direction, overlaps with the left end portion of the interior space Sp. The electronic component 101 is a heating element. The electronic component 101 is, for example, an IC (Integrated Circuit). The heat that the electronic component 101 generates is transmitted in the down direction of the stacked body 12. Then, the heat that the electronic component 101 generates is transmitted to the left portion of the ground conductor layer 22. Since water is present in the interior space Sp, water evaporates from the left portion of the ground conductor layer 22.

Water vapor moves in the right direction in the interior space Sp. In this case, the water vapor is cooled. As a result, the water vapor becomes water in the right end portion of the interior space Sp and attaches to the ground conductor layer 22.

Herein, the surface roughness of the lower principal surface (the second principal surface) of the ground conductor layer 22 (the first conductor layer) is greater than the surface roughness of the upper principal surface (the first principal surface) of the ground conductor layer 22 (the first conductor layer). According to this, the lower principal surface of the ground conductor layer 22 defines and functions as a wick. Therefore, the water moves in the left direction on the lower principal surface of the ground conductor layer 22. In this manner, the ground conductor layer 22 and the interior space Sp define and function as a heat pipe. As a result, an improvement in heat dissipation of the multilayer substrate 10a is achieved. Since the remaining structure of the multilayer substrate 10a is the same or substantially the same as the structure of the multilayer substrate 10, the description is omitted. The multilayer substrate 10a achieves the same or substantially the same advantageous effects as the multilayer substrate 10.

In addition, in the multilayer substrate 10a, a material of the insulator layers 16a-16e is, for example, a resin having a water absorption rate of about 0.1% or less. In this manner, the water absorption rate of the material of the insulator layers 16a-16e is low, so that the water in the interior space Sp is absorbed by the insulator layers 16a-16e and is significantly reduced from being discharged to the outside of the stacked body 12.

### Second Modification

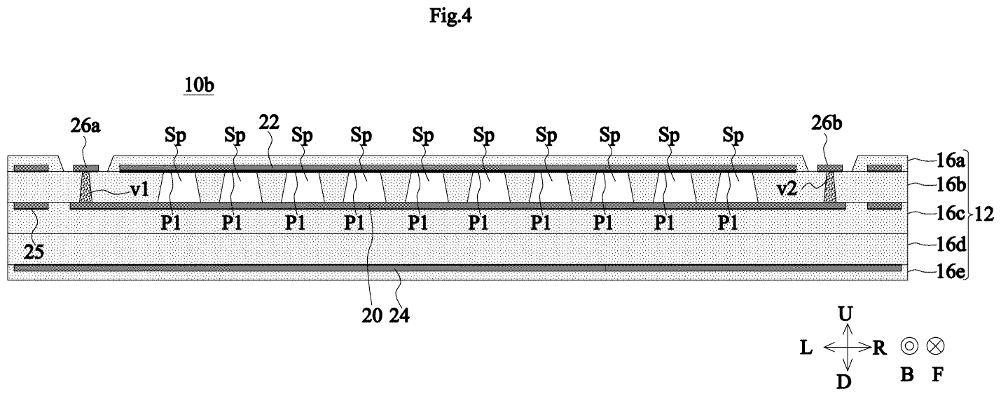

Hereinafter, a multilayer substrate 10b according to a second modification of an example embodiment of the present invention will be described with reference to drawings. FIG. 4 is a cross-sectional view of the multilayer substrate 10b.

The multilayer substrate 10b is different from the multilayer substrate 10 in the following points.

A plurality of interior spaces Sp are provided.

The signal conductor layer 20 and the ground conductor layer 25 adhere to the lower principal surface of the insulator layer 16b.

The plurality of interior spaces Sp are provided in the insulator layer 16b. The plurality of interior spaces Sp, when viewed in the down direction, overlap with the signal conductor layer 20. The plurality of interior spaces Sp are arranged in a line along the signal conductor layer 20. Since the remaining structure of the multilayer substrate 10b is the same or substantially the same as the structure of the multilayer substrate 10, the description is omitted. The multilayer substrate 10b achieves the same or substantially the same advantageous effects as the multilayer substrate 10.

According to the multilayer substrate 10b, a portion of the upper principal surface of the signal conductor layer 20 is supported by the insulator layer 16b. According to this, the position of the signal conductor layer 20 is significantly reduced from shifting from a designed value. In addition, the heat that the signal conductor layer 20 generates is transmitted in the up direction through the insulator layer 16b. According to this, an improvement in heat dissipation of the multilayer substrate 10b is achieved. Therefore, even when the upper principal surface of the signal conductor layer 20 is not roughened, the heat dissipation is able to be assured.

### Third Modification

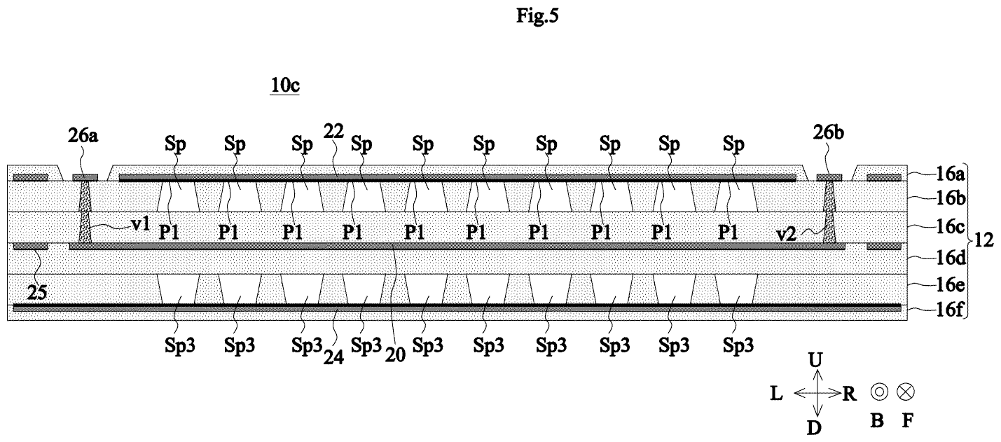

Hereinafter, a multilayer substrate 10c according to a third modification of an example embodiment of the present invention will be described with reference to drawings. FIG. 5 is a cross-sectional view of the multilayer substrate 10c.

The multilayer substrate 10c is different from the multilayer substrate 10b in the following points.

The insulator layer 16e is located between the insulator layer 16d and the insulator layer 16f.

The ground conductor layer 24 adheres to the lower principal surface of the insulator layer 16e.

A plurality of interior spaces Sp3 are provided.

The plurality of interior spaces Sp3 are provided in the insulator layer 16e. The plurality of interior spaces Sp3, when viewed in the down direction, overlap with the signal conductor layer 20. The plurality of interior spaces Sp3 are arranged in a line along the signal conductor layer 20. Since the remaining structure of the multilayer substrate 10c is the same or substantially the same as the structure of the multilayer substrate 10b, the description is omitted. The multilayer substrate 10c achieves the same or substantially the same advantageous effects as the multilayer substrate 10.

### Fourth Modification

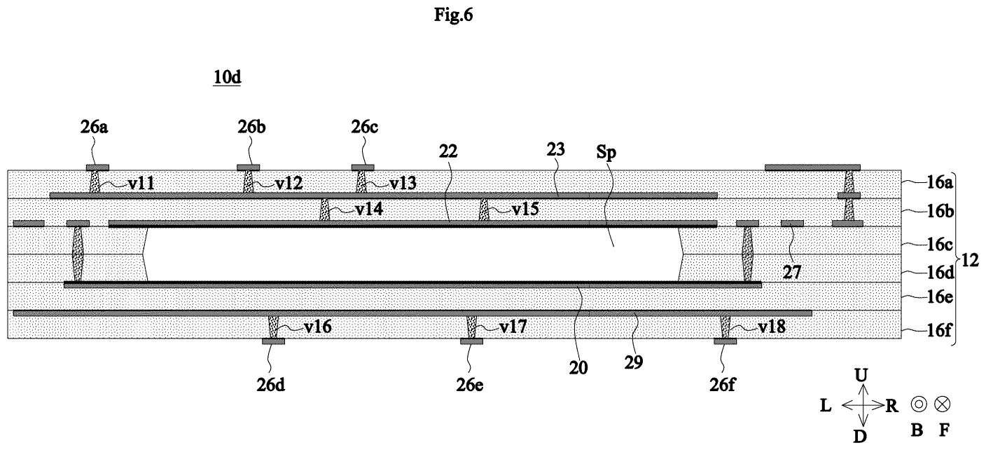

Hereinafter, a multilayer substrate 10d according to a fourth modification of an example embodiment of the present invention will be described with reference to drawings. FIG. 6 is a cross-sectional view of the multilayer substrate 10d.

The multilayer substrate 10d is different from the multilayer substrate 10 in that ground conductor layers 23 and 29, mounting electrodes 26a-26f, and a signal conductor layer 27 are further provided. The mounting electrodes 26a-26c adhere to the upper principal surface of the insulator layer 16a. The mounting electrodes 26d and 26e adhere to the lower principal surface of the insulator layer 16f. The ground conductor layer 23 adheres to the upper principal surface of the insulator layer 16b. The signal conductor layer 27 adheres to the upper principal surface of the insulator layer 16c. The ground conductor layer 29 adheres to the lower principal surface of the insulator layer 16e.

The interlayer connection conductor v11 electrically connects the mounting electrode 26a and the ground conductor layer 23. The interlayer connection conductor v12 electrically connects the mounting electrode 26b and the ground conductor layer 23. The interlayer connection conductor v13 electrically connects the mounting electrode 26c and the ground conductor layer 23. The interlayer connection conductors v14 and v15 electrically connect the ground conductor layer 22 and the ground conductor layer 23. The interlayer connection conductor v16 electrically connects the mounting electrode 26d and the ground conductor layer 29. The interlayer connection conductor v17 electrically connects the mounting electrode 26e and the ground conductor layer 29. The interlayer connection conductor v18 electrically connects the mounting electrode 26f and the ground conductor layer 29. Since the remaining structure of the multilayer substrate 10d is the same or substantially the same as the structure of the multilayer substrate 10, the description is omitted. The multilayer substrate 10d achieves the same or substantially the same advantageous effects as the multilayer substrate 10.

In the multilayer substrate 10d, the interlayer connection conductors v14 and v15 are connected to the ground conductor layer 22. According to this, the heat from the ground conductor layer 22 is discharged into the atmosphere through the interlayer connection conductors v11-v15 and the mounting electrodes 26a-26c.

In the multilayer substrate 10d, the signal conductor layer 27 is located at the upper right of the interior space Sp. According to this, the heat dissipation is performed through the signal conductor layer 27.

In the multilayer substrate 10d, the mounting electrodes 26a-26f are provided. According to this, heat is transmitted to a mother substrate through the mounting electrodes 26a-26f.

### Fifth Modification

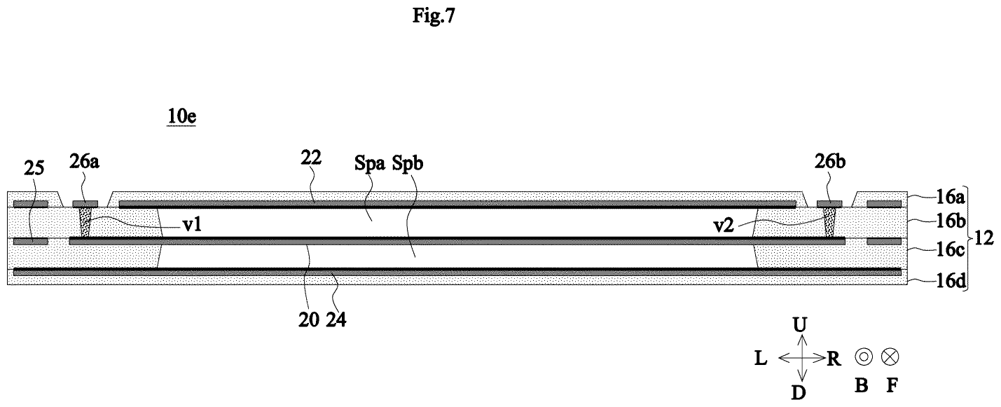

Hereinafter, a multilayer substrate 10e according to a fifth modification of an example embodiment of the present invention will be described with reference to drawings. FIG. 7 is a cross-sectional view of the multilayer substrate 10e.

The multilayer substrate 10e is different from the multilayer substrate 10 in that interior spaces Spa and Spb are provided above and below the signal conductor layer 20. More specifically, the signal conductor layer 20 is located on the lower principal surface of the insulator layer 16b. Then, the interior space Spa is provided in the insulator layer 16b. The interior space Spb is provided in the insulator layer 16c. According to this, the transmission loss of the signal conductor layer 20 is further reduced. Since the remaining structure of the multilayer substrate 10e is the same or substantially the same as the structure of the multilayer substrate 10, the description is omitted. The multilayer substrate 10e achieves the same or substantially the same advantageous effects as the multilayer substrate 10.

### Electronic Device

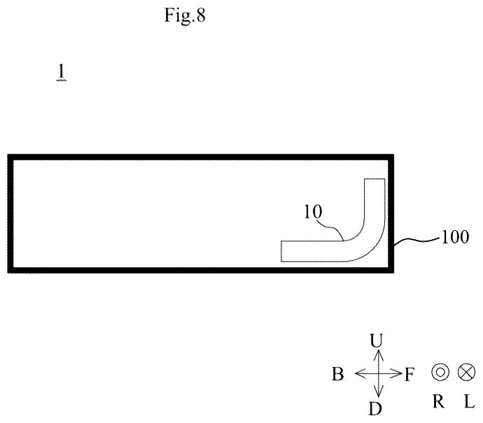

Hereinafter, a structure of an electronic device 1 according to an example embodiment of the present invention will be described with reference to drawings. FIG. 8 is a cross-sectional view of the electronic device 1 including the multilayer substrate 10.

The electronic device 1 includes the multilayer substrate 10 and a housing 100. The housing 100 stores the multilayer substrate 10. The electronic device 1 is a wireless communication terminal such as a smartphone, for example. In addition, the multilayer substrate 10 is bent. In addition, when the multilayer substrate 10 comes into contact with the housing 100, heat transfer is efficiently performed from a heating source to the housing 100, and a heat dissipation effect is improved.

### Other Example Embodiments

Multilayer substrates according to the present invention are not limited to the multilayer substrates 10 and 10a-10e according to the above-described example embodiments and modifications, and may be changed within the scope of the present invention. The structures of the multilayer substrates 10 and 10a-10e may be optionally combined.

The surface roughness of the exposed portion P1 may be greater than the surface roughness of the lower principal surface of the signal conductor layer 20. Accordingly, the surface roughness of portions other than the exposed portion P1 of the upper principal surface of the signal conductor layer 20 does not need to be greater than the surface roughness of the lower principal surface of the signal conductor layer 20.

The entire or substantially the entire upper surface and the entire or substantially the entire lower surface of the interior space Sp may be covered with the conductor layer.

The interior space Sp may not be an enclosed space that is not connected to a space outside the stacked body 12.

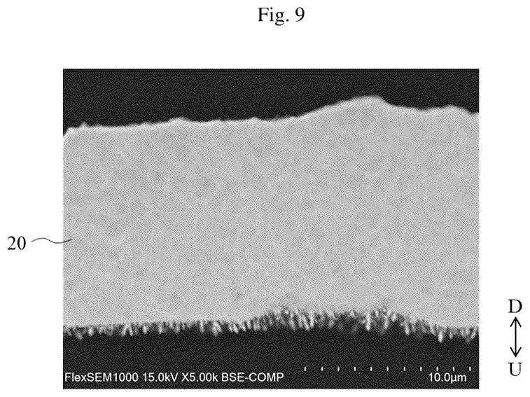

As shown in the photograph of FIG. 9, a surface with great height difference in a short wavelength is regarded as a surface with great surface roughness.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A multilayer substrate comprising:
a stacked body; and
a first conductor layer; wherein
the stacked body includes a plurality of insulator layers stacked in a stacking direction;
the first conductor layer is provided in the stacked body;
an interior space is provided in the stacked body;
the first conductor layer includes a first principal surface and a second principal surface;
the second principal surface includes an exposed portion exposed to the interior space and a portion adhered to the plurality of insulator layers; and
a surface roughness of the second principal surface is greater than a surface roughness of the first principal surface.

2. The multilayer substrate according to claim 1, wherein
the first conductor layer defines a signal conductor layer; and
at least a portion of the signal conductor layer, when viewed in the stacking direction, overlaps the interior space.

3. The multilayer substrate according to claim 1, wherein, in the interior space, a fluid that vaporizes at about 25 degrees or more to about 200 degrees or less is provided.

4. The multilayer substrate according to claim 1, wherein a material of the plurality of insulator layers includes a resin with a water absorption rate of about 0.1% or less.

5. The multilayer substrate according to claim 1, wherein a thermal expansion coefficient of the plurality of insulator layers in the stacking direction is greater than a thermal expansion coefficient of the plurality of insulator layers in a direction orthogonal or substantially orthogonal to the stacking direction.

6. The multilayer substrate according to claim 1, wherein a material of the plurality of insulator layers includes a liquid crystal polymer.

7. The multilayer substrate according to claim 1, wherein the plurality of insulator layers are fused between adjacent insulator layers in the stacking direction.

8. The multilayer substrate according to claim 1, wherein
the multilayer substrate further includes a second conductor layer;
the second conductor layer is provided in the stacked body; and
the interior space is located, in the stacking direction, between the first conductor layer and the second conductor layer.

9. The multilayer substrate according to claim 1, wherein the interior space is an enclosed space that is not connected to a space outside the stacked body.

10. An electronic device comprising the multilayer substrate according to claim 1.

11. The electronic device according to claim 10, wherein
the first conductor layer defines a signal conductor layer; and
at least a portion of the signal conductor layer, when viewed in the stacking direction, overlaps the interior space.

12. The electronic device according to claim 10, wherein, in the interior space, a fluid that vaporizes at about 25 degrees or more to about 200 degrees or less is provided.

13. The electronic device according to claim 10, wherein a material of the plurality of insulator layers includes a resin with a water absorption rate of about 0.1% or less.

14. The electronic device according to claim 10, wherein a thermal expansion coefficient of the plurality of insulator layers in the stacking direction is greater than a thermal expansion coefficient of the plurality of insulator layers in a direction orthogonal or substantially orthogonal to the stacking direction.

15. The electronic device according to claim 10, wherein a material of the plurality of insulator layers includes a liquid crystal polymer.

16. The electronic device according to claim 10, wherein the plurality of insulator layers are fused between adjacent insulator layers in the stacking direction.

17. The electronic device according to claim 10, wherein
the multilayer substrate further includes a second conductor layer;
the second conductor layer is provided in the stacked body; and
the interior space is located, in the stacking direction, between the first conductor layer and the second conductor layer.

18. The electronic device according to claim 10, wherein the interior space is an enclosed space that is not connected to a space outside the stacked body.
